(19) United States
(12) Patent Application Publication
(10) Pub. No.: US 2007/0026691 A1
(43) Pub. Date: Feb. 1, 2007

(54) Low-field non-contact charging apparatus for testing substrates

(75) Inventors: Lawrence Levit, Alamo, CA (US); Peter Gefter, So. San Francisco, CA (US); John Menear, Santa Cruz, CA (US)

Correspondence Address: MKS Instruments Inc., 1750 North Loop Road, Alameda, CA, 94502, US

(73) Assignee: MKS Instruments Inc.

(21) Appl. No.: 11/449,260

(22) Filed: Jun. 7, 2006

Related U.S. Application Data
(60) Provisional application No. 60/696,946, filed on Jul. 7, 2005.

(51) Int. Cl. H01L 21/00

(52) U.S. Cl. 438/795

(57) ABSTRACT

An apparatus and method for charging substrates without introducing high electric fields into the work environment. A non-contact charging plate is combined with a source of bipolar air (or gas) ions to effect the charging. This method is useful for studying the effects of static charge in charge sensitive processes. Substrates to be charged include semiconductor wafers, media disks, reticles, and flat panel glasses. In many cases, the shape of the apparatus is similar to industry-standard carriers. Hence, charging can be done robotically.

### CROSS-REFERENCE TO RELATED APPLICATIONS

This application claims the benefit of U.S. Provisional Application No. 60/696,946 filed Jul. 7, 2005 entitled “WAFER CHARGING APPARATUS”.

### STATEMENT REGARDING FEDERALLY SPONSORED RESEARCH

Not Applicable

### REFERENCE TO A MICROFICHE APPENDIX

Not Applicable

### BACKGROUND OF THE INVENTION

1. Field of the Invention

This invention relates to a static charging apparatus, which is designed to place a static charge onto a substrate. In particular, this charging apparatus is applicable to static sensitive or particle sensitive substrates, where direct contact or strong electric fields could damage thin film structures deposited on the surface of the substrate.

Primary applications include the charging of semiconductor wafers, disk drives, reticles, and flat panel displays for testing purposes. Testing applications require a high degree of repeatability. In addition, the ability to charge wafers, disk drives, reticles, and flat panel displays within an industry-standard carrier simplifies ESD related testing.

2. Description Of Related Art

Historically, high mono-polar electric fields are used to intentionally induce charges onto the surface of a nearby substrate. Charging electrodes or charging wires produce the high mono-polar electric field and high ionic current. Applied voltages can exceed ±15,000 volts.

Intentional charging is used with newspaper webs, plastic extruders, powder coat painters, copiers, and printers. There are other industrial uses. High electric fields as well as high ionic currents in the milliampere range are acceptable in these applications.

Intentional charging is seldom used within the semiconductor, disk drive, reticle, or flat panel display manufacturing facilities. Semiconductor, disk drive, reticle, or flat panel display manufacturing facilities are concerned with eliminating static charges—not creating them. Lower or negligible static charges correlate to better yields and more reliable products.

Paradoxically, the goal of decreasing or eliminating static charge levels in semiconductor, disk drive, reticle, or flat panel display fabrication facilities has been hindered. Improvements require feedback from controlled ESD tests, and the controlled tests require intentional charging. For example, the effect of charged wafers on a semiconductor process may be compared with the effect of electrically neutral wafers in that same process.

On its face, the goals are contradictory. Opposing needs exist. To decrease static charge levels for long term manufacture, static charge levels must be increased during the short term on selected test substrates.

Resolution of conflicting goals is required. Test substrates must be charged to meaningful levels, but the manufacturing process must not be degraded. Intentional charging via high mono-polar electric fields and currents is unacceptable. Although substrates under test could be charged to meaningful levels, using high mono-polar electric fields embodies an unacceptable risk within the manufacturing environment. Product could be damaged or lost.

Note that electric fields and ionic currents are not attenuated by non-conductors, and electric fields are attenuated slowly by static dissipative materials. A high voltage mono-polar charging electrode may affect manufacturing processes at large distances from the charging electrode. A low intensity electric field method is needed to reduce risks.

Test practicality is a further consideration. Semiconductor, disk drive, reticle, or flat panel display products are handled robotically. It would be desirable to charge the test substrates within an industry-standard carrier, within a modified industry-standard carrier, or on a robotically accessible station. Industry-standard dimensions and robotically accessed carriers minimize human errors in test procedures. This practical charging need is not addressed by prior art charging methods.

Direct contact charging methods are not useful. Non-conductive test substrates cannot be charged by the direct contact with a high voltage electrode. And particle contamination is an undesirable by-product of direct contact.

A new method of charging test substrates is needed.

### BRIEF SUMMARY OF THE INVENTION

This instant invention is a non-contact low-intensity field charging method that combines a conductive charging plate and a grounded bipolar air ionizer. The substrate to be charged is placed between the charging plate and the bipolar air ionizer. Neither the charging plate nor the ionizer makes any direct contact with the substrate.

To place charges onto the substrate, the operator (1) applies a known and adjustable voltage to a charging plate, and (2) directs air ions from a bipolar air ionizer to the side of the isolated substrate that faces away from the charging plate.

Common substrates include silicon wafers, silicon oxide wafers, reticles with pellicles, reticles without pellicles, disk media, plain glass plates, chromed glass plates, quartz plates, unprocessed flat panel display glass, and processed flat panel display glass. The inventive concept is not limited to these examples.

The charging plate projects an electric field through the isolated substrate, regardless of whether the substrate is conductive, dissipative, or non-conductive. This is true because the substrate is stationed on non-conductive supports.

Air (or gas) ions are moved by the electric field, which is projected through the substrate. Negative air ions are moved toward positive electric fields, and positive air ions are moved toward negative electric fields. Hence, the charges placed onto the substrate have the opposite polarity as the voltage applied to the charging plate.

The shape and material composition of the charger may incorporate the shape and material composition of an industry-standard substrate carrier. For example, to charge 300 mm wafers, the charger may embody the shape of a FOUP (front opening universal pod) or a FOSB (front opening shipping box). To charge reticles, the charger may embody the shape of a reticle carrier. And to charge a glass plate, the charger may take the shape of a glass processing station.

The surface resistivity of the charger body should be greater than 10E13 ohms/square, and preferably greater than 10E16 ohms/square. Useful materials for the charger body (or supports within the charger body) include fluorocarbons (Teflons), chlorofluorocarbons, polymeric ethers (eg, PEEK), polycarbonate, polypropylene, polyethylene, and polymeric acrylates. The above chemical classes are not a complete listing.

This charging method does not require the application of high voltages to the charging plate. Many tests can be performed with less than 1000 volts on the charging plate. And since the air ionizer is bipolar and electrically balanced, its electric field averages to nearly zero volts/inch within a relatively short distance from the ionizer. For charging very sensitive substrates, nuclear or X-ray ionizers may be employed.

Objects of this invention are: (1) provide a charging method that can operate at low intensity fields and low voltages, (2) provide a charging apparatus that can operate at low intensity fields and low voltages, (3) enable charging of wafers, media disks, reticles, and flat panel display glass regardless of surface patterning, (4) utilize balanced (or substantially balanced) bipolar ionizers to create the deposited charge, (5) utilize a non-contacting charging plate to provide an electric field that attracts ions to the substrate, (6) provide a method for testing the effect of static charge on a process, (7) perform charging inside a structure that approximates the shape of industry-standard carriers or industry-standard stations, (8) perform charging inside an industry-standard carrier that is accessible with a robot, and (9) perform efficiency tests on different means of static charge neutralization.

### BRIEF DESCRIPTION OF THE DRAWINGS

FIG. 1 is a diagram of a center slice of one embodiment of a general charger. The slice is taken from top to bottom and viewed from the front.

FIG. 2 is a pictorial diagram of a wafer charger that modifies an industry-standard front opening shipping box (FOSB). Two wafers can be charged simultaneously in this embodiment.

FIG. 3 is a pictorial diagram of a reticle charger. As shown, one reticle is being charged.

FIG. 4 is a two dimensional diagram of a glass plate charger. It is applicable to testing in the flat panel industry.

### DETAILED DESCRIPTION OF THE INVENTION

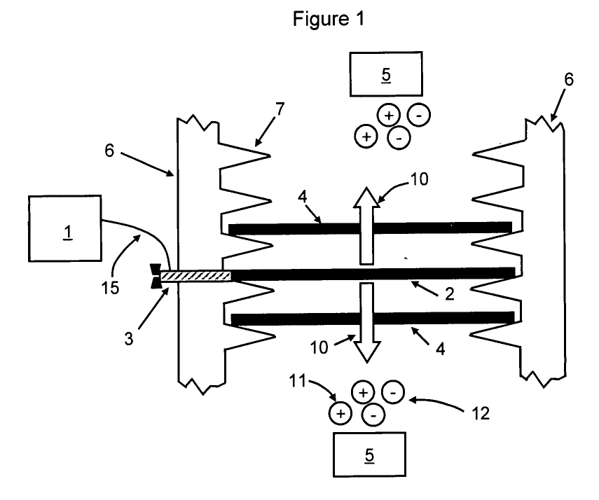

FIGS. 1 through 4 show the interconnection of the charger's components. A power supply 1 applies a voltage through a wire 15 and connector 3 to a conductive or dissipative charging plate 2. The voltage applied to the charging plate 2 generates an electric field 10, which projects through two test wafers 4. The wafers 4 rest in slots 7.

A substantially balanced air (or gas) ionizer 5 provides positive air ions 11 and negative air ions 12. (In all following text and claims, the term “air ions” shall mean “air or gas ions”.) Positive air ions 11 and negative air ions 12 are directed by an electrical field 10 to the top of the top substrate and to the bottom of the bottom substrate. That is, air ions are placed on the side of the substrate which faces away from the charging plate 2. The substrate is often (but not always) a semiconductor wafer 4, a reticle 16, a media disk, or a glass plate 17.

The electric field 10 moves air ions of only one polarity toward the substrate. If the charging plate 2 is positive, negative air ions 12 are deposited onto the substrate. If the charging plate 2 is negative, positive air ions 11 are deposited onto the substrate.

The substrate will continue to acquire charge until the net electric field intensity in space between the substrate and the ionizer 5 is close to zero. This occurs when the electric field created by the acquired charge of the substrate is equal and opposite to the electric field produced by the charging plate 2.

Testing with Faraday Cups and Faraday FOUPs has shown excellent charging repeatability. With +1000 volts on the charging plate 2, acquired wafer 4 charges were −27±2 nanoCoulombs (10⁻⁹ Coulombs) at the 95% confidence level. For this experiment, the wafers 4 were located at a distance equal to two slots from the charging plate 2. Electrostatic field meters may also be used to monitor charging levels.

Charge magnitude of the substrate (at constant charging plate 2 voltage) can be changed by altering the distance between the substrate and the charging plate 2. Lower charges accompany greater separation distances.

Since the charger body 6 is non-conductive, charges acquired by the substrate remain stable after the charging plate 2 is returned to ground potential (if the ionizer 5 is off before the charge plate is grounded). For oxide semiconductor wafers in a polycarbonate charger 6, virtually no charge loss was apparent after 12 storage days.

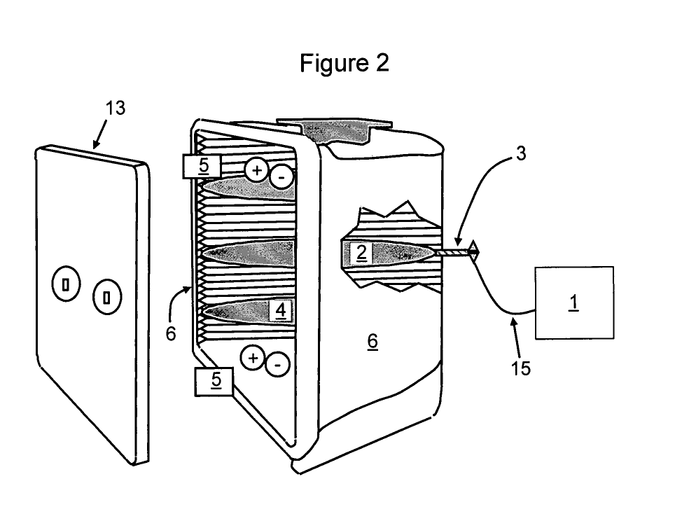

FIG. 2 shows an embodiment of the charger used for semiconductor wafer 4 charging. In this case, a commercially available FOSB (front opening shipping box) is utilized. The charging plate 2 is placed between the two wafers 4 to be charged.

The prototype utilized a threaded connector which fit into a tapped hole in a FOSB. However, any common penetrating connector may be used, providing that it is conductive and contacts the charging plate inside the charger body.

The charging plate may be fixed in place or may be removable. A removable plate is useful since it can be removed prior to transporting charged substrates.

Using a FOSB (front opening shipping box) is particularly useful. Because a FOSB fits onto a SEMI Standard loading platform, charged wafers can be passed through wafer processing equipment without human handling. The FOSB door 13 is automatically removed, and wafers are picked up by an integral equipment robot. Later, the wafers 4 are returned by the same robot, and the FOSB door 13 is replaced.

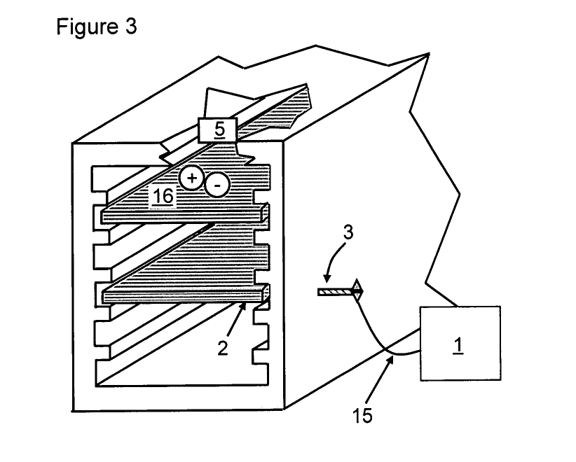

In FIG. 3, the inventive concept is applied to reticle 16 charging. In this example, only one reticle is shown. But two reticles can be charged simultaneously. The charging plate 2 in FIG. 3 has the shape of a reticle, but the shape charging plate 2 isn't critical.

Note that the shape of the reticle 16 charger can be the same as an industry-standard reticle carrier. This allows reticle processing equipment to be studied without human handling.

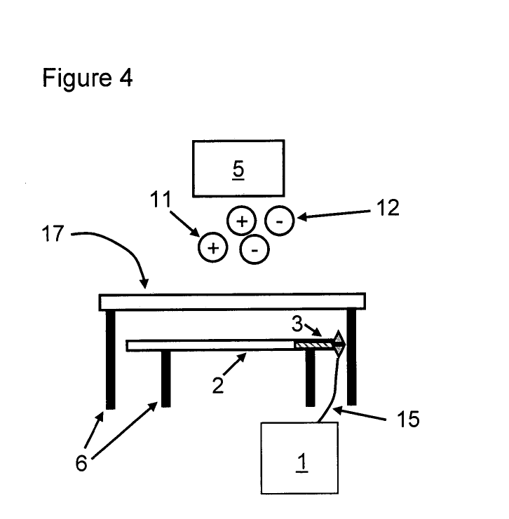

In FIG. 4, the embodiment is directed toward glass plate 17 charging. The flat panel display industry uses glass plates as a starting material. Hence, this charger is of interest to the flat panel display industry.

The method of charging glass plates 17 is the same as the method of charging wafers 4, reticles 16, and media disks. Both the glass plate 17 and the charging plate 2 are installed on isolative supports 6. A combination of air (or gas) ions plus a charged conductive plate produce a charged glass plate, which can then be used to quantify the effects of static charges as well as charge neutralization on the process.

In some applications, the connector 3 is not essential. For instance, refer to FIG. 2. With the door 13 open, the wire 15 may directly contact the charging plate 2 through the door 13 opening. FIGS. 1 through 4 follow this page.

The invention claimed is:

1. An apparatus for charging substrates comprising:
a non-conductive charger body or a charger body having non-conductive supports;
a conductive or static dissipative charging plate;
a bipolar air or gas ionizer; and
a power supply or a charge plate monitor.

2. claim 1 where said substrates are semiconductor wafers, reticles, media disks, or glass plates.

3. claim 1 where said substrates are conductive or static dissipative.

4. claim 1 where said substrates are fully or partly non-conductive.

5. claim 1 where said non-conductive charger body comprises a commercially available front opening shipping box for semiconductor wafers.

6. claim 1 where said non-conductive charger body has a surface or volume resistivity which is greater than 10E13 ohms.

7. claim 1 where said charger body or said supports contain fluorocarbons (teflons), chlorofluorocarbons, polymeric ethers (eg, PEEK), polycarbonate, polypropylene, polyethylene, or polymeric acrylates.

8. claim 1 where said supports comprise slots for holding said substrates.

9. claim 1 where said charger body is shaped to fit correctly onto the load station of an equipment system under test.

10. claim 1 where said charging plate has a surface resistivity, which is less than 10E13 ohms per square.

11. claim 1 where said charging plate comprises a p-type or n-type bare silicon wafer.

12. claim 1 where said charging plate comprises a metal, a metal alloy, a conducting plastic, or a static dissipative plastic.

13. claim 1 where said ionizer uses corona discharge, nuclear disintegration sources, or ionizing radiation to produce air or gas ions.

14. claim 1 where said substrates are transported by a robot, which is an integral component of an equipment system under test.

15. A method of charging one or more substrates comprising:
placing said substrates into a non-conductive charger body or into a charger with non-conductive supports;
charging at least one charging plate; and
generating air or gas ions that are deposited onto said substrates.

16. claim 15 where said substrates are semiconductor wafers, reticles, media disks, or glass plates.

17. claim 15 where said placing utilizes isolative slots integrated into said charger body.

18. claim 15 where said placing is done above or below said charging plate.

19. claim 15 where said charging is done with a power supply or charge plate monitor connected with a wire to said charging plate.

20. claim 15 where said charging is done with a power supply or charge plate monitor connected with a wire and a connector to said charging plate.

21. claim 15 where said generating is performed with a substantially electrically balanced bipolar ionizer.

22. claim 21 where said bipolar ionizer uses corona discharge, nuclear disintegration sources, or ionizing radiation to produce air or gas ions.

23. claim 22 where said bipolar ionizer is grounded.

24. claim 15 where said charging is monitored with a Faraday Cup or a Faraday FOUP.

25. claim 15 where said charging is monitored with an electrostatic field meter.

26. claim 1 where said bipolar air or gas ionizer is grounded.
